(19) United States
(12) Patent Application Publication
(10) Pub. No.: US 2021/0066546 A1
(43) Pub. Date: Mar. 4, 2021

(54) NITRIDE SEMICONDUCTOR ELEMENT AND NITRIDE SEMICONDUCTOR ELEMENT PRODUCTION METHOD

(71) Applicant: NIKKISO CO., LTD., Tokyo (JP)

(72) Inventors: Mitsugu WADA, Ishikawa (JP); Cyril PERNOT, Ishikawa (JP)

(73) Assignee: NIKKISO CO., LTD., Tokyo (JP)

(21) Appl. No.: 16/958,497

(22) PCT Filed: Oct. 31, 2018
(86) PCT No.: PCT/JP2018/040540

§ 371 Date: Jun. 26, 2020

(30) Foreign Application Priority Data
Dec. 28, 2017 (JP) 2017-254379

(51) Int. Cl. H01L 33/16; H01L 33/00; C30B 29/40; C30B 23/00; C30B 25/16; C30B 23/02

(52) U.S. Cl. CPC H01L 33/16; H01L 33/0075; C30B 29/406; H01L 33/06; C30B 23/002; C30B 25/16; C30B 23/02; C30B 29/403

(57) ABSTRACT

A nitride semiconductor light-emitting element 1 contains an AlN layer 22 having a crystalline quality within a predetermined range and an n-type AlGaN formed atop the AlN layer 22 and having a predetermined Al composition ratio formed atop the AlN layer 22. In addition, as the crystalline quality falling within the predetermined range, the AlN layer 22 has a crystalline quality corresponding to an X-ray rocking curve half-width of 350 to 520 (arcsec vis-à-vis a (10-12) surface. As the predetermined Al composition ratio, the n-type AlGaN has an Al composition ratio of 40% to 70%.

### TECHNICAL FIELD

The invention relates to a nitride semiconductor element and a nitride semiconductor element production method.

### BACKGROUND ART

In recent years, nitride semiconductor elements such as transistors or light-emitting diodes have been available, and nitride semiconductor elements with improved crystalline quality, have been under development (see Patent Document 1).

### CITATION LIST

### Patent Document

Patent Document 1: JP 2013-16711A

### SUMMARY OF INVENTION

### Technical Problem

A nitride semiconductor element described in Patent Document 1 is provided with a single crystal substrate, an AlN layer formed on one surface of the single crystal substrate, a first nitride semiconductor layer formed on the AlN layer and having a first conductivity type, a light-emitting layer formed of an AlGaN-based material and located on the first nitride semiconductor layer on the opposite side to the AlN layer, and a second nitride semiconductor layer having a second conductivity type and formed on the light-emitting layer on the opposite side to the first nitride semiconductor layer, and the nitride semiconductor element has a configuration in which a density of N-polar AlN crystal in the AlN layer is not more than 1,000/cm², and a full width at half maximum of an X-ray rocking curve for the AlN (10-12) plane of the AlN layer obtained using X-ray diffraction ω-scan is not more than 500 arcsec. In case of the nitride semiconductor element described in Patent Document 1, reliability in electrical characteristics of the nitride semiconductor element is increased by improving crystalline quality of the AlN layer.

However, the present inventors found that, in nitride semiconductor elements configured that an n-type AlGaN is formed as a first nitride semiconductor layer on an AlN layer, crystalline quality of the n-type AlGaN as the first nitride semiconductor layer is not necessarily improved even when the crystalline quality of the AlN layer is improve, but crystalline quality of such an n-type AlGaN can be improved when crystalline quality of the AlN layer falls within a predetermined range.

Therefore, it is an object of the invention to provide a nitride semiconductor element including an n-type AlGaN located on an AlN layer which is formed to have a crystalline quality within a predetermined range to improve the crystalline quality of the n-type AlGaN, and a nitride semiconductor element production method.

### Solution to Problem

A nitride semiconductor element in one aspect of the invention includes an AlN layer having a crystalline quality within a predetermined range, and an n-type AlGaN formed above the AlN layer and having a predetermined Al composition ratio, wherein an n-AlGaN mix value that is a full width at half maximum of an X-ray rocking curve for a (10-12) plane of the n-type AlGaN is not more than a specified value, and wherein the AlN layer is formed such that an AlN mix value that is a full width at half maximum of an X-ray rocking curve for a (10-12) plane of the AlN layer is more than a specified value based on relation between the AlN mix value and the n-AlGaN mix value.

A nitride semiconductor element production method in another aspect of the invention includes forming an AlN layer having a crystalline quality within a predetermined range, and forming an n-type AlGaN that is located above the AlN layer and has a predetermined Al composition ratio, setting an n-AlGaN mix value of the n-type AlGaN, which is a full width at half maximum of an X-ray rocking curve for a (10-12) plane to be not more than a specified value, and setting an AlN mix value that is a full width at half maximum of an X-ray rocking curve for a (10-12) plane of the AlN layer to be more than a specified value based on relation between the AlN mix value and the n-AlGaN mix value.

### ADVANTAGEOUS EFFECTS OF INVENTION

According to an embodiment of the invention, it is possible to provide a nitride semiconductor element including an n-type AlGaN located on an AlN layer which is formed to have a crystalline quality within a predetermined range to improve the crystalline quality of the n-type AlGaN, and a nitride semiconductor element production method.

### BRIEF DESCRIPTION OF DRAWINGS

FIG. 1 is a schematic vertical cross-sectional view showing a configuration of a nitride semiconductor element in an embodiment of the present invention.

FIG. 2 is a diagram illustrating data of n-AlGaN mix values and emission outputs of the semiconductor element.

FIG. 3 is a graph showing a relation between the n-AlGaN mix values and the emission outputs of the semiconductor element shown in FIG. 2.

FIG. 4 is a diagram illustrating data of AlN mix values and n-AlGaN mix values.

FIG. 5 is a graph showing a correlation between the AlN mix values and the n-AlGaN mix values shown in FIG. 4.

### DESCRIPTION OF EMBODIMENT

### Embodiment

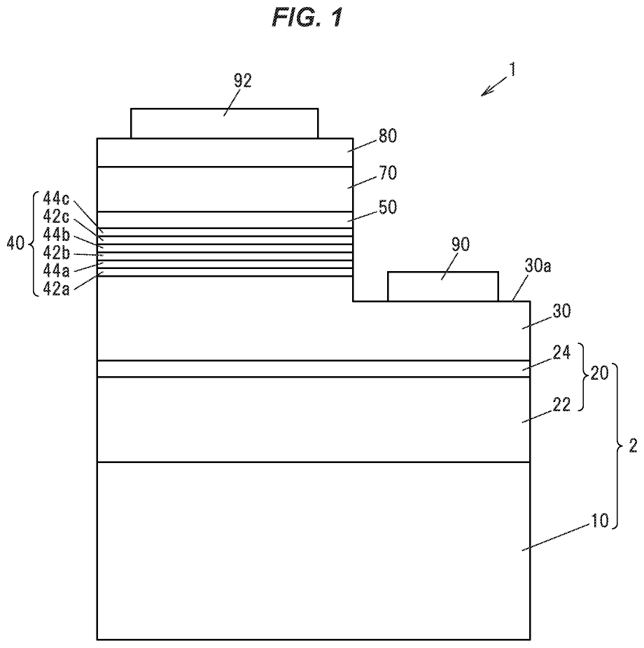

An embodiment of the invention will be described in reference to FIG. 1. The embodiment below is described as a preferred example for implementing the invention. Although some part of the embodiment specifically illustrates various technically preferable matters, the technical scope of the invention is not limited to such specific aspects. In addition, a scale ratio of each constituent element in each drawing is not necessarily the same as the actual scale ratio of the nitride semiconductor element.

Configuration of Nitride Semiconductor Element

FIG. 1 is a schematic vertical cross-sectional view showing a configuration of a nitride semiconductor element in an embodiment of the invention. A nitride semiconductor element 1 includes, e.g., transistor, laser diode (LD), light-emitting diode (LED), etc. In the present embodiment, a light-emitting diode emitting light having a wavelength in an ultraviolet region (particularly, deep ultraviolet light with a central wavelength of 250 nm to 350 nm) will be described as an example of the nitride semiconductor element 1 (hereinafter, also simply referred to as “the semiconductor element 1”).

As shown in FIG. 1, the semiconductor element 1 includes a substrate 10, a buffer layer 20, an n-type cladding layer 30, an active layer 40 including a multi-quantum well layer, an electron blocking layer 50, a p-type cladding layer 70, a p-type contact layer 80, an n-side electrode 90 and a p-side electrode 92.

The semiconductor which can be used to form the semiconductor element 1 is, e.g., a binary, ternary, or quaternary group III nitride semiconductor which is expressed by AlₓGa_{y}In_{1-x-y}N (0≤x≤1, 0≤y≤1, 0≤x+y≤1,). In addition, the group III elements thereof may be partially substituted with boron (B) or thallium (Tl), etc., and N may be partially substituted with phosphorus (P), arsenic (As), antimony (Sb) or bismuth (Bi), etc.

The substrate 10 is, e.g., a sapphire substrate including sapphire (Al₂O₃). Besides the sapphire (Al₂O₃) substrate, e.g., an aluminum nitride (AlN) substrate or an aluminum gallium nitride (AlGaN) substrate may be used as the substrate 10.

The buffer layer 20 is formed on the substrate 10. The buffer layer 20 includes an AlN layer 22 and a u-AlₚGa₁₋ₚN layer 24 (0≤p≤1) which is undoped and formed above the AlN layer 22. The AlN layer 22 has a crystalline quality within a predetermined range. The details will be described later. The substrate 10 and the buffer layer 20 constitute a foundation structure 2. However, when the substrate 10 is an AlN substrate or an AlGaN substrate, the buffer layer 20 may not be necessarily provided.

The n-type cladding layer 30 is formed on the foundation structure 2. The n-type cladding layer 30 is a layer formed of n-type AlGaN (hereinafter, also simply referred to as “n-AlGaN”) and is, e.g., an Al_{q}Ga_{1-q}N layer (0≤q≤1) doped with silicon (Si) as an n-type impurity. Alternatively, germanium (Ge), selenium (Se), tellurium (Te) or carbon (C), etc., may be used as the n-type impurity. The n-type cladding layer 30 has a thickness of about 1 μm to 5 μm. The n-type cladding layer 30 may have a single layer or a multilayer structure.

The active layer 40 including a multi-quantum well layer is formed on the n-type cladding layer 30. The active layer 40 is a layer including a multi-quantum well layer in which three AlᵣGa₁₋ᵣN barrier layers 42a, 42b, 42c, including the barrier layer 42a located on the n-type cladding layer 30 side and the barrier layer 42c located on the electron blocking layer 50 (described later) side in the multi-quantum well layer, and three AlₛGa₁₋ₛN well layers 44a, 44b, 44c (0≤r≤1, 0≤s≤1, r>s) are alternately stacked. Although the active layer 40 in the present embodiment is provided with three each of the barrier layers 42 and the well layers 44, the number of layers is not necessarily limited to three, and may be not more than two, or not less than four.

The electron blocking layer 50 is formed on the active layer 40. The electron blocking layer 50 is formed of AlN. The electron blocking layer 50 has a thickness of about 1 nm to 10 nm. Optionally, the electron blocking layer 50 may include a layer formed of p-type AlGaN (hereinafter, also simply referred to as “p-AlGaN”). in addition, the electron blocking layer 50 is not necessarily limited to a p-type semiconductor layer and may be an undoped semiconductor layer.

The p-type cladding layer 70 is formed on the electron blocking layer 50. The p-type cladding layer 70 is a layer formed of p-AlGaN and is, e.g., an AlₜGa₁₋ₜN cladding layer (0≤t≤1) doped with magnesium (Mg) as a p-type impurity. Alternatively, zinc (Zn), beryllium (Be), calcium (Ca), strontium (Sr) or barium (Ba), etc., may be used as the p-type impurity. The p-type cladding layer 70 has a thickness of about 300 nm to 700 nm.

The p-type contact layer 80 is formed on the p-type cladding layer 70. The p-type contact layer 80 is, e.g., a p-type GaN layer doped with a high concentration of impurity such as Mg.

The n-side electrode 90 is formed on a certain region of the n-type cladding layer 30. The n-side electrode 90 is formed of, e.g., a multilayered film formed by sequentially stacking titanium (Ti), aluminum (Al), Ti and gold (Au) on the n-type cladding layer 30.

The p-side electrode 92 is formed on the p-type contact layer 70. The p-side electrode 92 is formed of, e.g., a multilayered film formed by sequentially stacking nickel (Ni) and gold (Au) on the p-type contact layer 70.

Relation Between Crystalline Quality of N-AlGaN and Emission Output of Semiconductor Element

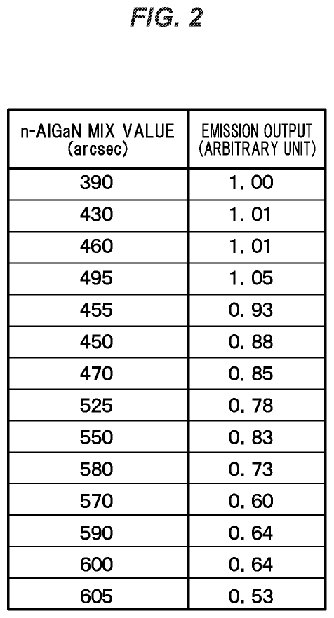

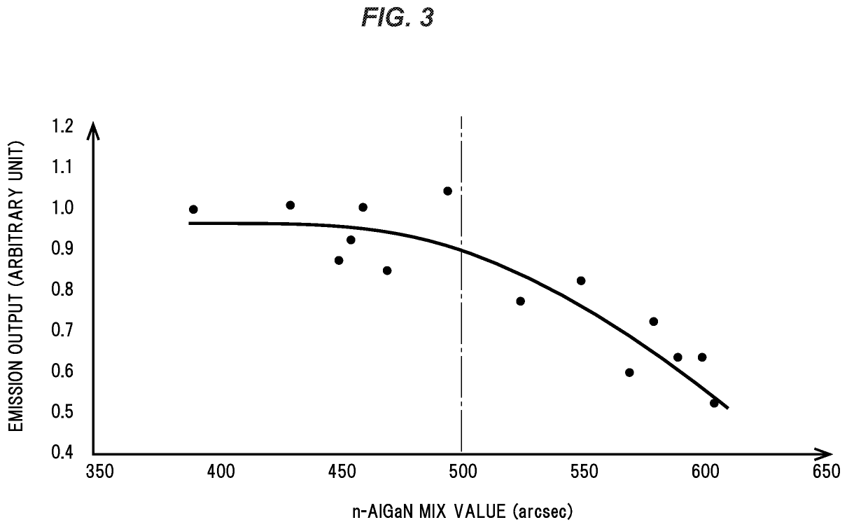

Next, a relation between quality of crystal (also simply called “crystalline quality”; the expression “crystallinity” can be also used) of n-AlGaN constituting the n-type cladding layer 30 and emission output of the semiconductor element will be described in reference to FIGS. 2 and 3. For the purpose of evaluating a relation between the crystalline quality of the n-AlGaN constituting the n-type cladding layer 30 and the emission output of the semiconductor element 1, the present inventors conducted experiments to investigate a relation between a mix value of the n-AlGaN (hereinafter, also simply referred to as “the n-AlGaN mix value”) and the emission output of the semiconductor element 1. The n-AlGaN mix value here is a full width at gro of an X-ray rocking curve (arcsec) for a (10-12) plane (a Mixed plane) of the n-AlGaN crystal obtained using X-ray diffraction ω-scan, and is an example of a typical indicator of crystalline quality of n-AlGaN. The smaller n-AlGaN mix value means that n-AlGaN has a better crystalline quality.

FIG. 2 is a diagram illustrating data of the n-AlGaN mix values and the emission outputs of the semiconductor element. FIG. 3 is a graph showing a relation between the n-AlGaN mix values and the emission outputs of the semiconductor element shown in FIG. 2. In FIG. 3, the horizontal axis indicates the n-AlGaN mix value (arcsec) and the vertical axis indicates the emission output (arbitrary unit) of the semiconductor element 1. The solid line in FIG. 3 is a projection line schematically showing a pattern of change in the emission output (arbitrary unit) of the semiconductor element 1 with respect to the n-AlGaN mix value (arcsec). The dash-dot line in FIG. 3 is a projection line indicating 500 arcsec. The emission output can be measured by various known methods. In this Example, a current was supplied between the n-side electrode 90 and the p-side electrode 92 which are described above, and emission output was measured by a photodetector placed under the semiconductor element 1, as an example.

As shown in FIGS. 2 and 3, the emission output of the semiconductor element 1 changes when the n-AlGaN mix value is around 500 arcsec. In detail, the emission output of the semiconductor element 1 starts to decrease when the n-AlGaN mix value exceeds 500 arcsec. This experiment shows that the n-AlGaN mix value is preferably not more than 550 arcsec, and the n-AlGaN mix value is more preferably not more than 500 arcsec, to suppress a decrease in the emission output of the semiconductor element 1.

Relation Between AlN Mix Value and N-AlGaN Mix Value

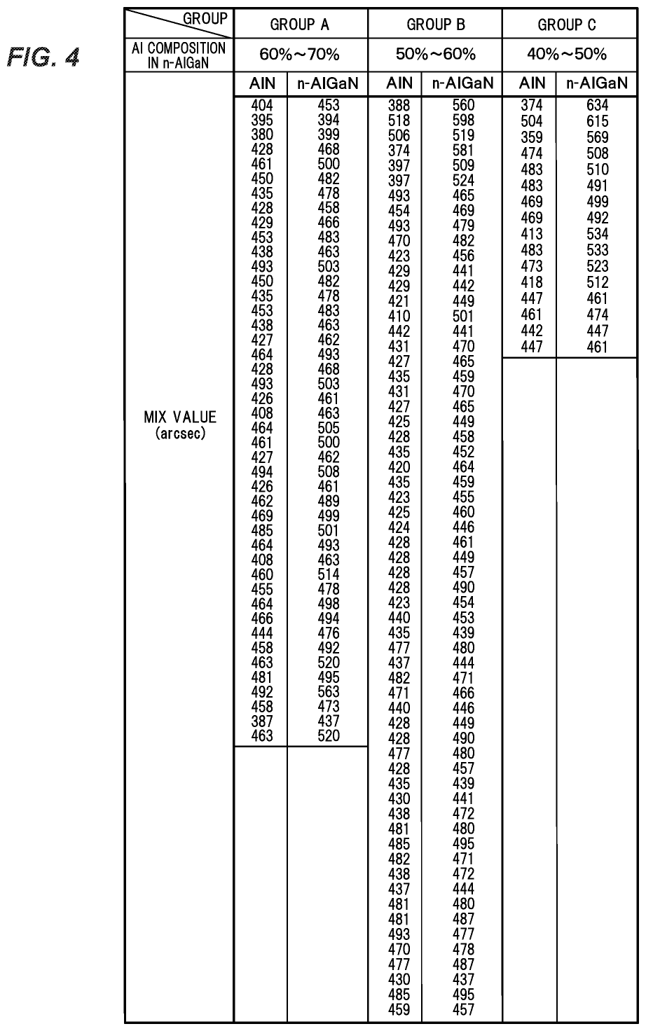

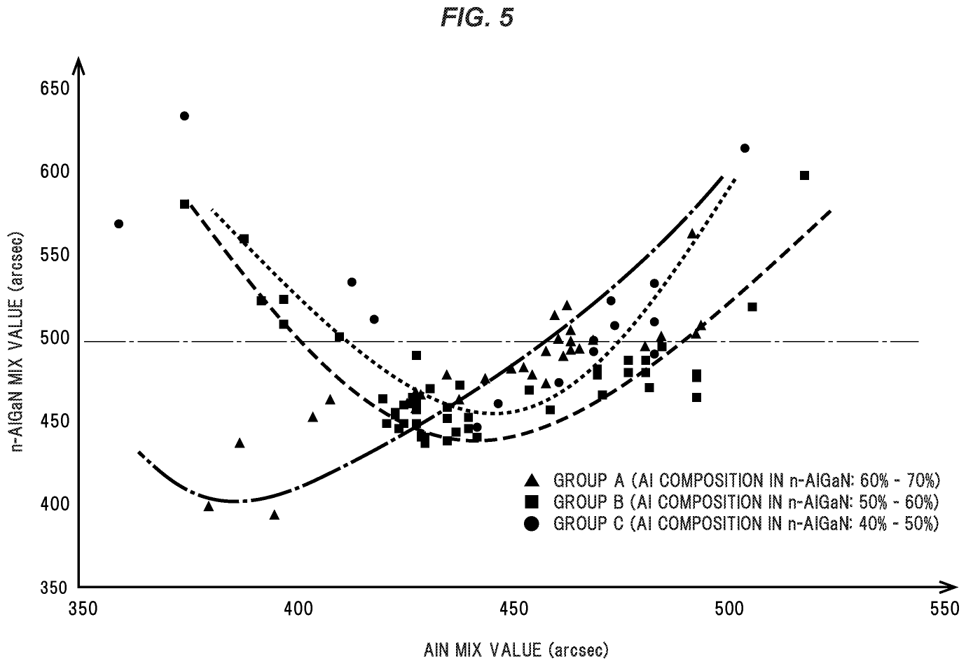

Next, a relation between a mix value of AlN (hereinafter, also simply referred to as “the AlN mix value”) and the n-AlGaN mix value will be described in reference to FIGS. 4 and 5. The AlN mix value here is a full width at half maximum of an X-ray rocking curve (arcsec) for a (10-12) plane (a Mixed plane) of AlN crystal constituting the AlN layer 22 obtained using X-ray diffraction ω-scan, and is an example of a typical indicator of crystalline quality of AlN. The smaller AlN mix value means that AlN has a better crystalline quality. As a result of intensive study, the present inventors found that there is a correlation between the AlN mix value and the n-AlGaN mix value. The details will be described below.

In detail, the present inventors firstly made one hundred and twenty-two of the above-described semiconductor elements 1 each including the n-type cladding layer 30 formed of n-AlGaN with an AlN mole fraction (%) (hereinafter, also referred to as “an Al composition ratio”) of 40% to 70%. Next, the one hundred and twenty-two semiconductor elements 1 were divided into three groups (Group A, Group B and Group C) based on the range of the Al composition ratio. Then, the AlN mix value and the n-AlGaN mix value of each semiconductor element 1 in each group were measured.

FIG. 4 is a diagram in which data of the AlN mix values and the n-AlGaN mix values are shown in the table. As shown in FIG. 4, the semiconductor elements 1 having the n-type cladding layers 30 formed of n-AlGaN with the Al composition ratios of 60% to 70% were classified as Group A. The semiconductor elements 1 having the n-type cladding layers 30 formed of n-AlGaN with the Al composition ratios of 50% to 60% were classified as Group B. The semiconductor elements 1 having the n-type cladding layers 30 formed of n-AlGaN with the Al composition ratios of 40% to 50% were classified as Group C. Forty-four out of the one hundred and twenty-two semiconductor elements 1 fell into Group A. Sixty-two out of the one hundred and twenty-two semiconductor elements 1 fell into Group B. Sixteen out of the one hundred and twenty-two semiconductor elements 1 fell into Group C.

FIG. 5 is a graph showing a correlation between the AlN mix value and the n-AlGaN nix value shown in FIG. 4. In FIG. 5, triangles indicate data from the semiconductor elements 1 classified as Group A, squares indicate data from the semiconductor elements 1 classified as Group B, and circles indicate data from the semiconductor elements 1 classified as Group C. In addition, the dash-dot line in FIG. 5 is a line schematically showing a pattern of change in the n-AlGaN mix value with respect to the AlN mix value in the data from the semiconductor elements 1 in Group A. The dashed line is a line schematically showing a pattern of change in the n-AlGaN mix value with respect to the AlN mix value in the data from the semiconductor elements 1 in Group B. The dotted line is a line schematically showing a pattern of change in the n-AlGaN mix value with respect to the AlN mix value in the data from the semiconductor elements 1 in Group C. The thin line is a line indicating the n-AlGaN mix value of 500 arcsec.

As shown in FIG. 5, the graph showing the n-AlGaN mix value with respect to the AlN mix value has a shape which is substantially convex downward. In other words, the relation between the AlN mix value and the n-AlGaN mix value is such that the n-AlGaN mix value has a local minimum with respect to the AlN mix value.

In detail, in Group A, i.e., in case of the semiconductor elements 1 in which the n-AlGaN has an Al composition ratio of 60% to 70%, the n-AlGaN mix value has a local minimum when the AlN mix value is around 390±10 arcsec (see the dash-dot line in FIG. 5). In Group B, i.e., in case of the semiconductor elements 1 in which the n-AlGaN has an Al composition ratio of 50% to 60%, the n-AlGaN mix value has a local minimum when the AlN mix value is around 450±10 arcsec (see the dashed line in FIG. 5). In Group C, i.e., in case of the semiconductor elements 1 in which the n-AlGaN has an Al composition ratio of 40% to 50%, the n-AlGaN mix value has a local minimum when the AlN mix value is around 450±10 arcsec (see the dotted line in FIG. 5).

These results show that the n-AlGaN mix value decreases with a decrease in the AlN mix value when the AlN mix value is more than a specific value (the AlN mix value at which the n-AlGaN mix value has a local minimum), and the n-AlGaN mix value increases with a decrease in the AlN mix value when the AlN mix value is not more than the specific value. In other words, the above results show that the crystalline quality of the n-AlGaN is improved together with the crystalline quality of the AlN when the AlN has a crystalline quality within a predetermined range, but the crystalline quality of the n-AlGaN decreases even with a further increase in the crystalline quality of the AlN when the crystalline quality of the AlN is not less than a certain level. When applying these results to the semiconductor element 1, the AlN layer 22 when having a predetermined crystalline quality can improve the crystalline quality of the n-type AlGaN.

Meanwhile, the n-AlGaN mix value of more than 500 arcsec and the n-AlGaN mix value of not more than 500 arcsec are both present in the respective results of Group A, Group B and Group C. In other words, there is a certain range of the AlN mix value which provides the n-AlGaN mix value of not more than 500±10 arcsec.

As described above, a decrease in the emission output of the semiconductor element 1 is suppressed when the n-AlGaN mix value is not more than 500±10 arcsec (see FIG. 3). When fitting the result shown in FIG. 3 to the data shown in FIG. 5, it is considered that when the AlN mix value is within a certain range, the n-AlGaN mix value is kept down to not more than 500±10 arcsec and a decrease in the emission output of the semiconductor element 1 is thereby suppressed. In other words, it is considered that a decrease in the emission output of the semiconductor element 1 is suppressed when AlN has a crystalline quality within a predetermined range.

In detail, as shown in FIG. 5, the predetermined range of the AlN mix value in the results of Group A is not more than 480 arcsec. The predetermined range of the AlN mix value in the results of Group B is 380 to 520 arcsec. The predetermined range of the AlN mix value in the results of Group C is 410 to 490 arcsec. As the results of Group B and Group C show, the AlN mix value has the predetermined range defined between a value of not less than a first predetermined value and a value of not more than a second predetermined value which are determined to suppress a decrease in the emission output of the semiconductor element 1. In other words, for the AlN mix value, there is the predetermined range defined between the lower limit and the upper limit at which a decrease in the emission output of the semiconductor element 1 is suppressed.

When consolidating the results of Group A, Group B and Group C, the predetermined range of the AlN mix value is 350 to 480 arcsec when the Al composition ratio in the n-AlGaN is 40% to 70%. Particularly when consolidating the results of Group B and Group C, the predetermined range of the AlN mix value is 380 to 520 arcsec when the Al composition ratio in the n-AlGaN is 40% to 60%.

In other words, when the Al composition ratio in the n-AlGaN is 40% to 70%, the crystalline quality of the AlN layer 22 within the predetermined range is a crystalline quality corresponding to an X-ray rocking curve full width at half maximum of 350 to 520 arcsec for the (10-12) plane. Then, when the Al composition ratio in the n-AlGaN is 40% to 60%, the crystalline quality of the AlN layer 22 within the predetermined range is a crystalline quality corresponding to an X-ray rocking curve full width at half maximum of 380 to 520 arcsec for the (10-12) plane. Furthermore, when the Al composition ratio in the n-AlGaN is 40% to 50%, the crystalline quality of the AlN layer 22 within the predetermined range is a crystalline quality corresponding to an X-ray rocking curve full width at half maximum of 410 to 490 arcsec for the (10-12) plane.

Semiconductor Element Production Method

Next, a method for producing the semiconductor element 1 will be described. The buffer layer 20, the n-type cladding layer 30, the active layer 40, the electron blocking layer 50 and the p-type cladding layer 70 are sequentially formed in this order on the substrate 10 by high temperature growth. These layers can be grown and formed by a well-known epitaxial growth method such as Metal Organic Chemical Vapor Deposition (MOCVD) method, Molecular Beam Epitaxy (MBE) method, or Halide Vapor Phase Epitaxy (HVPE) method.

The step of forming the AlN layer 22 of the buffer layer 20 includes a formation step performed so that the X-ray rocking curve full width at half maximum for the (10-12) plane of AlN crystal falls within the predetermined range. When the AlN layer 22 is formed by MOCVD, crystal growth can be performed under the conditions of a growth temperature in the range of 1150 to 1350° C. and a doping amount of Ga in the range of about 1×10¹⁷ to 1×10¹⁸ (cm⁻³) so that the AlN layer as a film thickness of about 2 μm.

The X-ray rocking curve full width at half maximum for the (10-12) plane of the AlN crystal can be reduced by raising the growth temperature. The X-ray rocking curve full width at half maximum for the (10-12) plane of the AlN crystal can be reduced also by increasing the doping amount of Ga. Furthermore, the X-ray rocking curve full width at half maximum for the (10-12) plane of the AlN crystal can be reduced when increasing the film thickness of the AlN layer 22 to more than 2 μm. As such, the AlN layer 22 having a desired X-ray rocking curve full width at half maximum can be formed by appropriately changing at least one or more of the growth temperature, the doping amount of Ga and the film thickness of the AlN layer 22. In other words, to obtain the predetermined crystalline quality, the step of forming the AlN layer 22 includes at least one or more of the step of changing the growth temperature, the step of changing the doping amount of Ga, and the step of changing the film thickness of the AlN layer 22.

Meanwhile, the step of forming the n-type cladding layer 30 includes a formation step performed so that the n-AlGaN has the predetermined Al composition ratio.

Next, a mask is formed on the p-type cladding layer 70. Then, the active layer 40, the electron blocking stack body 50 and the p-type cladding layer 70 in the exposed region without the mask are removed. The active layer 40, the electron blocking stack body 50 and the p-type cladding layer 70 can be removed by, e.g., plasma etching. The n-side electrode 90 is formed on an exposed surface 30a of the n-type cladding layer 30 (see FIG. 1), and the p-side electrode 92 is formed on the p-type contact layer 80 which is formed after removing the mask. The n-side electrode 90 and the p-side electrode 92 can be formed by, e.g., a well-known method such as electron beam evaporation method or sputtering method. The semiconductor element 1 shown in FIG. 1 is thereby obtained.

Functions and Effects of the Embodiment

As described above, the semiconductor element 1 in the embodiment of the invention includes the AlN layer 22 of which X-ray rocking curve full width at half maximum for the (10-12) plane falls within the predetermined range, and the n-type cladding layer 30 formed of the n-type AlGaN with the predetermined Al composition ratio. When the n-type AlGaN has the, predetermined Al composition ratio, it is possible to suppress a decrease in the crystalline quality of the n-AlGaN by adjusting the X-ray rocking curve full width at half maximum for the (10-12) plane of the AlN layer 22 so as to fall within the predetermined range. As a result, it is possible to suppress a decrease in the emission output of the semiconductor element 1.

Summary of the Embodiment

Technical ideas understood from the embodiment will be described below citing the reference numerals, etc., used for the embodiment. However, each reference numeral, etc., described below is not intended to limit the constituent elements in the claims to the members, etc., specifically described in the embodiment.

[1] A nitride semiconductor element (1), comprising: an AlN layer (22) having a crystalline quality within a predetermined range; and an n-type AlGaN formed above the AlN layer and having a predetermined Al composition ratio, wherein an n-AlGaN mix value that is a full width at half maximum of an X-ray rocking curve for a (10-12) plane of the n-type AlGaN is not more than a specified value, and wherein the AlN layer is formed such that an AlN mix value that is a full width at half maximum of an X-ray rocking curve for a (10-12) plane of the AlN layer is more than a specified value based on relation between the AlN mix value and the n-AlGaN mix value.

[2] The nitride semiconductor element (1) described in the above [1], wherein the crystalline quality of the AlN layer (22) is a crystalline quality corresponding to the AlN mix value of 350 to 520 (arcsec), and the predetermined Al composition ratio in the n-type AlGaN is an Al composition ratio of 40% to 70%.

[3] The nitride semiconductor element (1) described in the above [2], wherein the crystalline quality of the AlN layer (22) is a crystalline quality corresponding to the AlN mix value of 380 to 520 (arcsec), and the predetermined Al composition ratio in the n-type AlGaN is an Al composition ratio of 40% to 60%.

[4] The nitride semiconductor element (1) described in the above [3], wherein the crystalline quality of the AlN layer (22) is a crystalline quality corresponding to the AlN mix value of 410 to 490 (arcsec), and the predetermined Al composition ratio in the n-type AlGaN is an Al composition ratio of 40% to 50%.

[5] A nitride semiconductor element (1) production method, comprising: forming an AlN layer (22) having a crystalline quality within a predetermined range; and forming an n-type AlGaN that is located above the AlN layer and has a predetermined Al composition ratio, setting an n-AlGaN mix value of the n-type AlGaN, which is a full width at half maximum of an X-ray rocking curve for a (10-12) plane to be not more than a specified value, and setting an AlN mix value that is a full width at half maximum of an X-ray rocking curve for a (10-12) plane of the AlN layer to be more than a specified value based on relation between the AlN mix value and the n-AlGaN mix value.

[6] The nitride semiconductor element (1) production method described in the above [5], wherein the forming the AlN layer (22) having the crystalline quality within the predetermined range comprises at least one or more of changing a growth temperature, changing a doping amount of Ga, and changing a film thickness of the AlN layer (22).

### REFERENCE SIGNS LIST

1: nitride semiconductor element (semiconductor element)
22: AlN layer

1. A nitride semiconductor element, comprising:
an AlN layer having a crystalline quality within a predetermined range; and
an n-type AlGaN formed above the AlN layer and having a predetermined Al composition ratio,
wherein an n-AlGaN mix value that is a full width at half maximum of an X-ray rocking curve for a (10-12) plane of the n-type AlGaN is not more than a specified value, and
wherein the AlN layer is formed such that an AlN mix value that is a full width at half maximum of an X-ray rocking curve for a (10-12) plane of the AlN layer is more than a specified value based on relation between the AlN mix value and the n-AlGaN mix value.

2. The nitride semiconductor element according to claim 1, wherein the crystalline quality of the AlN layer is a crystalline quality corresponding to the AlN mix value of 350 to 520 (arcsec), and the predetermined Al composition ratio in the n-type AlGaN is an Al composition ratio of 40% to 70%.

3. The nitride semiconductor element according to claim 2, wherein the crystalline quality of the AlN layer is a crystalline quality corresponding to the AlN mix value of 380 to 520 (arcsec), and the predetermined Al composition ratio in the n-type AlGaN is an Al composition ratio of 40% to 60%.

4. The nitride semiconductor element according to claim 3, wherein the crystalline quality of the AlN layer is a crystalline quality corresponding to AlN mix value of 410 to 490 (arcsec), and the predetermined Al composition ratio in the n-type AlGaN is an Al composition ratio of 40% to 50%.

5. A nitride semiconductor element production method, comprising:
forming an AlN layer having a crystalline quality within a predetermined range; and
forming an n-type AlGaN that is located above the AlN layer and has a predetermined Al composition ratio,
setting an n-AlGaN mix value of the n-type AlGaN, which is a full width at half maximum of an X-ray rocking curve for a (10-12) plane to be not more than a specified value, and
setting an AlN mix value that is a full width at half maximum of an X-ray rocking curve (arcsec) for a (10-12) plane of the AlN layer to be more than a specified value based on relation between the AlN mix value and the n-AlGaN mix value.

6. The nitride semiconductor element production method according claim 5, wherein the forming the AlN layer having the crystalline quality within the predetermined range comprises at least one or more of changing a growth temperature, changing a doping amount of Ga, and changing a film thickness of the AlN layer.
